(19) United States
(12) Patent Application Publication
(10) Pub. No.: US 2024/0065117 A1
(43) Pub. Date: Feb. 22, 2024

(54) SUPERCONDUCTING MONOLITHIC MICROWAVE INTEGRATED CIRCUIT PROCESSING

(71) Applicant: International Business Machines Corporation, Armonk, NY (US)

(72) Inventors: Michael Karunendra Selvanayagam, Ossining, NY (US); Nicholas A Masluk, Putnam Valley, NY (US)

(21) Appl. No.: 17/820,380

(22) Filed: Aug. 17, 2022

(51) Int. Cl. H10N 69/00; H01P 3/00; H01P 3/08

(52) U.S. Cl. CPC H10N 69/00; H01L 28/10; H01P 3/003; H01P 3/081

(57) ABSTRACT

One or more systems, devices, methods of use and/or methods of fabrication herein relate to superconducting monolithic microwave integrated circuits. According to an embodiment, a device comprises a monolithic microwave integrated circuit comprising a superconducting layer coupled to a first circuit element and to a second circuit element, wherein a material of the superconducting layer comprises Tantalum Nitride.

### BACKGROUND

The subject disclosure relates to monolithic microwave integrated circuits (MMICs), and more specifically to superconducting monolithic microwave integrated circuits.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, system, apparatuses, and methods are described that can facilitate operation of superconducting monolithic microwave integrated circuits.

According to an embodiment, a device can comprise a monolithic microwave integrated circuit comprising a superconducting passive element coupled (e.g., capacitively coupled, inductively coupled and/or coupled via an electrical contact) to a first circuit element and to a second circuit element, wherein a material of the superconducting passive element comprises Tantalum Nitride. An advantage of such device is that Tantalum Nitride superconducts at low temperatures (e.g., approximately temperatures below 4 Kelvin (K)), enabling a superconducting monolithic microwave integrated circuit.

In some embodiments, of the above described device, the device can further comprise a metal contact (e.g., a metal film or layer) deposited on the superconducting passive element. An advantage of such a device is that the metal contact enables the monolithic microwave integrated circuit to operate at low temperatures utilizing the superconducting passive element and at room temperature utilizing the metal contact.

According to another embodiment, a method can comprise operating a superconducting monolithic microwave integrated circuit, wherein the superconducting monolithic microwave integrated circuit comprises a superconducting passive element coupled to a first circuit element and to a second circuit element, wherein a material of the superconducting passive element comprises Tantalum Nitride. An advantage of such a method is that Tantalum Nitride superconducts at low temperatures, enabling a superconducting monolithic microwave integrated circuit.

In some embodiments of the above described method, the superconducting monolithic microwave integrated circuit can further comprise a metal contact (e.g., a metal film or layer) in contact with the superconducting passive element. An advantage of such a method is that the metal contact enables the superconducting monolithic microwave integrated circuit to operate at low temperatures utilizing the superconducting passive element and at room temperature utilizing the metal contact.

In another embodiment, a system can comprise a cryogenic refrigerator and a monolithic microwave integrated circuit comprising a superconducting layer coupled to a first circuit element and to a second circuit element, wherein a material of the superconducting layer comprises Tantalum Nitride, and wherein the monolithic microwave integrated circuit is located within the cryogenic refrigerator. An advantage of such a system is that as Tantalum Nitride superconducts at low temperatures, the cryogenic refrigerator can cool the microwave integrated circuit, thereby enabling a superconducting monolithic microwave integrated circuit.

Various other details of various embodiments described herein are presented in the following clauses.

CLAUSE 1: A device, comprising: a monolithic microwave integrated circuit comprising a superconducting passive element coupled to a first circuit element and to a second circuit element, wherein a material of the superconducting passive element comprises Tantalum Nitride. An advantage of such device is that Tantalum Nitride superconducts at low temperatures, enabling a superconducting monolithic microwave integrated circuit.

CLAUSE 2: The device of any preceding clause specified in the Summary, wherein the superconducting passive element comprises an inductor coupled to the first circuit element and to the second circuit element.

CLAUSE 3: The device of any preceding clause specified in the Summary, wherein the superconducting passive element comprises a transmission line coupled to the first circuit element and to the second circuit element.

CLAUSE 4: The device of any preceding clause specified in the Summary, wherein the superconducting passive element comprises an interconnect coupled to the first circuit element and to the second circuit element.

CLAUSE 5: The device of any preceding clause specified in the Summary, wherein the superconducting passive element comprises a coplanar waveguide coupled to the first circuit element and to the second circuit element.

CLAUSE 6: The device of any preceding clause specified in the Summary, wherein the superconducting passive element comprises a microstrip coupled to the first circuit element and to the second circuit element.

CLAUSE 7: The device of any preceding clause specified in the Summary, further comprising a metal contact on the superconducting passive element.

CLAUSE 8: The device of any preceding clause specified in the Summary, wherein the metal contact comprises at least one of Gold, Copper or Aluminum.

CLAUSE 9: A method, comprising: operating a superconducting monolithic microwave integrated circuit, wherein the superconducting monolithic microwave integrated circuit comprises: a superconducting passive element coupled to a first circuit element and to a second circuit element, wherein a material of the superconducting passive element comprises Tantalum Nitride. An advantage of such a method is that Tantalum Nitride superconducts at low temperatures, enabling a superconducting monolithic microwave integrated circuit.

CLAUSE 10: The method of any preceding clause specified in the Summary, wherein the superconducting passive element further comprises an inductor.

CLAUSE 11: The method of any preceding clause specified in the Summary, wherein the superconducting passive element further comprises a transmission line.

CLAUSE 12: The method of any preceding clause specified in the Summary, wherein the superconducting monolithic microwave integrated circuit further comprises a metal contact deposited on the superconducting passive element.

CLAUSE 13: The method of any preceding clause specified in the Summary, wherein the superconducting passive element further comprises an interconnect.

CLAUSE 14: A system, comprising: a cryogenic refrigerator; and a monolithic microwave integrated circuit comprising a superconducting layer coupled to a first circuit element and to a second circuit element, wherein a material of the superconducting layer comprises Tantalum Nitride, and wherein the monolithic microwave integrated circuit is located within the cryogenic refrigerator. An advantage of such a system is that as Tantalum Nitride superconducts at low temperatures, the cryogenic refrigerator can cool the microwave integrated circuit, thereby enabling a superconducting monolithic microwave integrated circuit.

CLAUSE 15: The system of any preceding clause specified in the Summary, wherein the superconducting layer comprises an inductor coupled to the first circuit element and to the second circuit element.

CLAUSE 16: The system of any preceding clause specified in the Summary, wherein the superconducting layer comprises a transmission line coupled to the first circuit element and to the second circuit element.

CLAUSE 17: The system of any preceding clause specified in the Summary, wherein the superconducting layer comprises an interconnect coupled to the first circuit element and to the second circuit element.

CLAUSE 18: The system of any preceding clause specified in the Summary, wherein the superconducting layer comprises a coplanar waveguide coupled to the first circuit element and to the second circuit element.

CLAUSE 19: The system of any preceding clause specified in the Summary, wherein the superconducting layer comprises a microstrip coupled to the first circuit element and to the second circuit element.

CLAUSE 20: The system of any preceding clause specified in the Summary, wherein the monolithic microwave integrated circuit further comprises a metal contact on the superconducting layer coupled to the first circuit element and to the second circuit element.

### DESCRIPTION OF THE DRAWINGS

FIG. 1 illustrates a diagram of an example, non-limiting top-down view of passive elements in a monolithic microwave integrated circuit in accordance with one or more embodiments described herein.

FIG. 2 illustrates a diagram of an example, non-limiting top-down view of superconducting passive elements in a superconducting monolithic microwave integrated circuit in accordance with one or more embodiments described herein.

FIG. 3 illustrates a diagram of an example, non-limiting top-down view of superconducting and non-superconducting passive elements in a superconducting monolithic microwave integrated circuit in accordance with one or more embodiments described herein.

FIG. 4 illustrates a flow diagram of an example, non-limiting method that can facilitate a process to fabricate a device constructed in accordance with one or more embodiments described herein.

FIG. 5 illustrates a flow diagram of an example, non-limiting method that can facilitate a process to fabricate a device constructed in accordance with one or more embodiments described herein.

FIG. 6 illustrates a flow diagram of an example, non-limiting method that can facilitate a process to fabricate a system constructed in accordance with one or more embodiments described herein.

FIG. 7 illustrates a block diagram of an example, non-limiting device, in accordance with one or more embodiments describe herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

Part of designing and building hardware for superconducting qubit-based quantum computers includes cryogenic microwave circuits. These circuit include a variety of passive and active devices including, but not limited to, filters, couplers, and amplifiers. As quantum computing systems scale, these components will likely move from discrete packaged devices to more integrated solutions, wherein these circuits may be fabricated in integrated circuit process. For realizing microwave circuits, monolithic microwave circuits are an attractive technology, since much of the manufacturing process is geared towards realizing key circuit elements of active and passive circuits in an integrated manner.

MMICs are a class of analog circuits which operate at microwave or radio frequencies, and are fabricated on a single die using a multi-layer lithographic process. MMICs can include both active circuits (e.g., circuits which dissipate static power, such as amplifiers and mixers) and passive circuits (e.g., circuits which do not dissipate static power, such as filters, splitters and couplers). Due to being fabricated on a single die, MMICs are an attractive option for integrated systems.

A generic MMIC fabrication process can consist of a process that defines circuit elements such as, transistors, resistors, interconnects, transmission lines, cross overs, capacitors, inductors, and through silicon vias (TSV) in different layers. Of these components, transmission lines and inductors often suffer from high conductor loss, due to the thin films (e.g., approximately 1 μm) used which limits transmission line and inductor performance, even at cryogenic temperatures. When deposited as a thin film on a substrate and cooled to low temperatures (e.g., approximately 4K or less), Tantalum Nitride (TaN) exhibits superconducting behavior. The exact superconducting temperature of the thin film material is dependent on its deposition conditions as well as the ratio of Tantalum to Nitride. Accordingly, TaN can be utilized as a material in super conductive components, thereby improving transmission line and inductor performance.

Many microwave applications can benefit from superconductors, as this can improve performance of the circuit. For example, filters incorporating superconducting materials can have sharper transitions. For cryogenic applications broadly, and quantum computing specifically, loss, performance and thermal considerations often call for a superconducting circuit, especially for those circuits operating at the lower temperature stages of a cryostat. As cryogenic applications and quantum computing already utilize cooling infrastructure, these applications can benefit from superconductivity without the need of additional cooling hardware. For example, as quantum computers utilize cryogenic refrigeration to cool the qubits and transmission lines within the quantum computer, superconducting MMICs can be included as components within the transmission lines without need for additional cryogenic hardware.

However, this desire for superconducting MMICs is often at odds with the general MMIC process, especially those offered via commercial foundry services. It is still desirable to be able to realize a superconducting monolithic microwave integrated circuit process. Accordingly, a superconducting MMIC can be produced utilizing conductive traces comprising TaN. As stated above, TaN superconducts at low temperatures (e.g., approximately 4K or less). Therefore, superconducting MMICs can be produced by patterning conductive elements in a TaN layer.

There are two potential layouts proposed in this disclosure. In an embodiment, the TaN layer is deposited solely as a transmission line/inductor/interconnect layer to realize superconducting circuit elements. In this embodiment, the circuit would function when cooled in a cryostat, but room-temperature operations would not be feasible since the TaN film would be resistive at room temperature. In another embodiment, a metal contact (e.g., a metal film/layer deposited along the entire superconducting passive element) can be deposited on top of the TaN layer (mimicking a very elongated contact). In this embodiment, the circuit would also operate at room temperature due to the metal contact, but when cooled, the superconducting properties of the TaN layer would dominate. It should be appreciated that when the TaN layer is utilized as a conductive layer, there may not be a resistive layer in the MMIC process. In an embodiment, resistors, such as for biasing or termination, can instead be incorporated as an off-chip component. For example, the MMIC can be coupled to a resistor, wherein the resistor is located on a separate chip from the MMIC.

Fabrication of MMICs can utilize multiple layers and material stacks. For example, MMIC fabrication can comprise a lithographic production method in which a series of layers are patterned and assembled together. For example, multiple materials such as gold and various other metals, can be patterned in layers according to lithographic patterns to realize circuit elements.

In an embodiment, a device can comprise a monolithic microwave integrated circuit comprising a superconducting passive element coupled to a first circuit element and to a second circuit element, wherein a material of the superconducting passive element comprises TaN. For example, a superconducting layer comprising TaN can be patterned. In various embodiments, this superconducting layer can comprise components such as inductors, transmission lines, interconnects, such as coplanar waveguides and microstrip, and/or any other components. These elements can then be utilized to pass a signal from a first circuit element to a second circuit element in the overall MMIC. For example, a superconducting layer comprising a transmission line can be coupled to a first circuit element and to a second circuit element. Therefore, a signal from the first circuit element can be transmitted to the second circuit element via the superconducting layer.

At room temperatures, TaN is highly resistive, and is used in some existing MMIC processes as highly resistive components. Such high resistivity made the use of TaN unsuitable for sensitive, signal carrying, elements in of microwave and/or RF devices of in existing MMICs. Therefore, some MMIC foundries already have experience with patterning TaN and the supply chains to procure TaN. Accordingly, existing MMIC fabrication processes can be modified to utilize TaN in superconducting elements, rather than as highly resistive components. By repurposing TaN to pattern conductive elements rather than resistive elements, a superconducting MMIC fabrication process can be realized that lowers manufacture costs when compared to other manufacture processes. For example, by utilizing TaN, start-up costs, design and development time, and production costs can be lowered when compared to completely new fabrication processes.

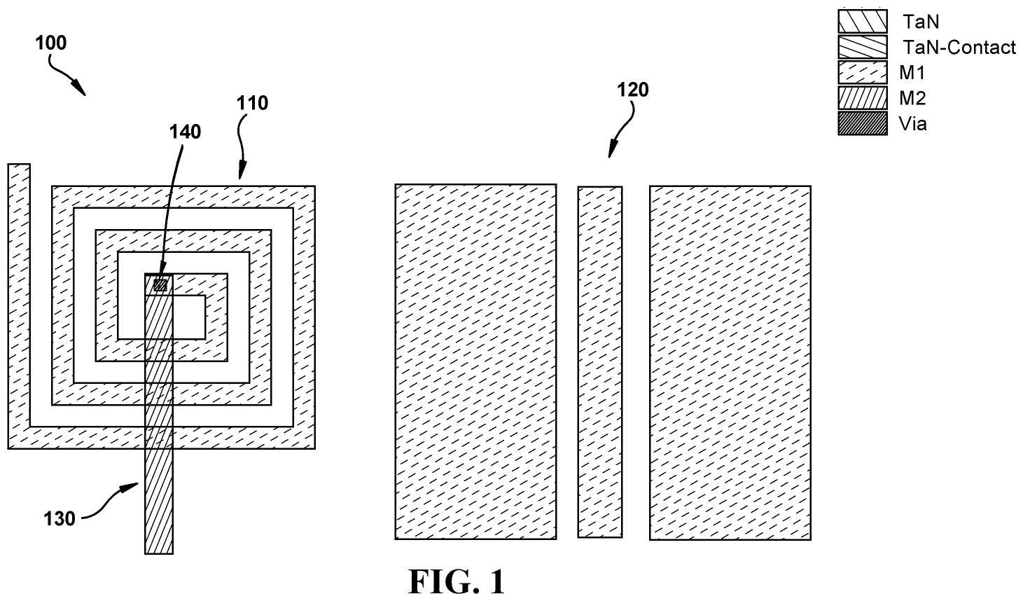

FIG. 1 illustrates a diagram of an example, non-limiting top-down view of passive elements in a monolithic microwave integrated circuit in accordance with one or more embodiments described herein. Repetitive description of like elements and/or processes employed in respective embodiments is omitted for sake of brevity.

Layer 100 comprises an inductor 110, a coplanar waveguide (CPW) transmission line 120, a crossover 130 and a via 140. As shown, in existing MMIC processes, the inductor 110 and the CPW transmission line 120 are patterned using a metal (M1). Accordingly, this use of a non-superconducting material can lead to resistive losses in the inductor 110, which can increase noise in devices such as low noise amplifiers or broaden filter cutoffs, thereby reducing performance.

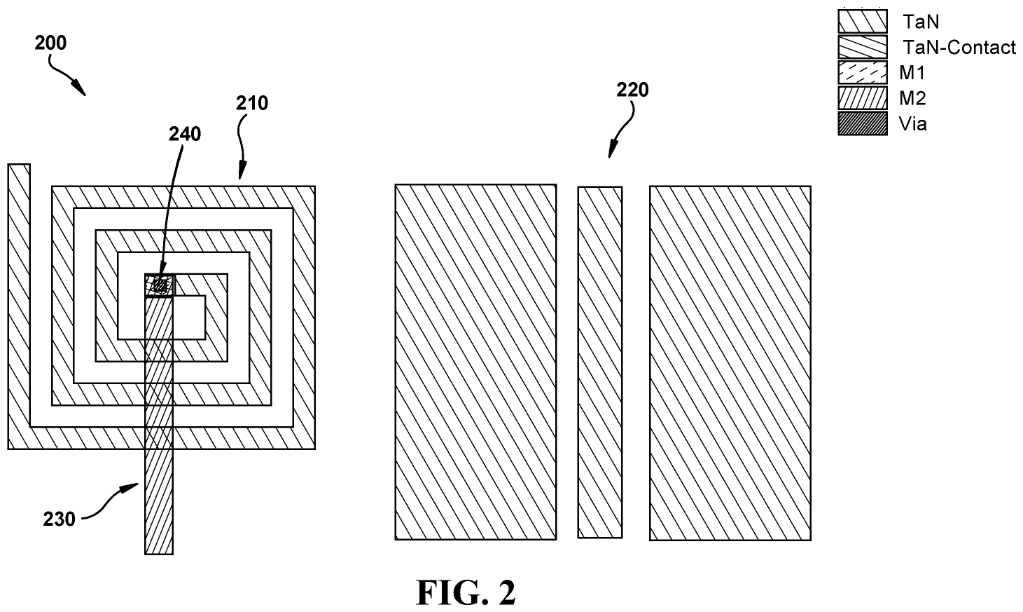

FIG. 2 illustrates a diagram of an example, non-limiting top-down view of superconducting passive elements in a superconducting monolithic microwave integrated circuit, in accordance with one or more embodiments described herein. Repetitive description of like elements and/or processes employed in respective embodiments is omitted for sake of brevity.

Layer 200 comprises an inductor 210, a coplanar waveguide (CPW) transmission line 220, a crossover 230 and a via 240. As shown, the inductor 210 and the CPW transmission line 220 can be patterned using TaN. By using TaN, the inductor 210 and the CPW transmission line 220 will superconduct at low temperatures, allowing the MMIC as a whole to act as a superconducting chip. This allows for the inductor 210 and CPW transmission line 220 to take on the same geometry (e.g., lithographic pattern) as the inductor 110 and the CPW transmission line 120 of layer 100, as shown in FIG. 1.

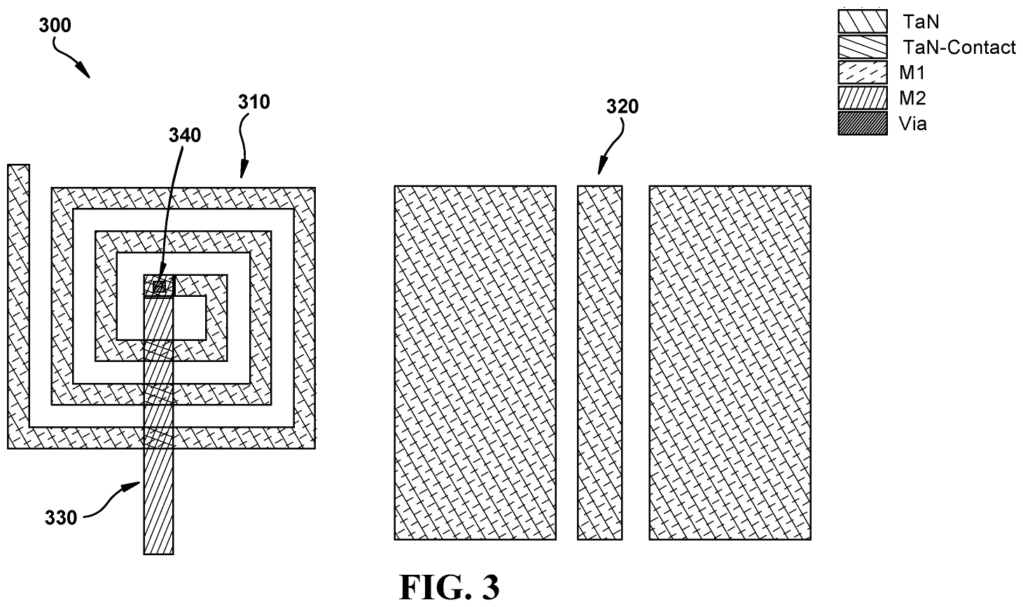

FIG. 3 illustrates a diagram of an example, non-limiting top-down view of superconducting and non-superconducting passive elements in a superconducting monolithic microwave integrated circuit in accordance with one or more embodiments described herein. Repetitive description of like elements and/or processes employed in respective embodiments is omitted for sake of brevity.

Layer 300 comprises an inductor 310, a coplanar waveguide (CPW) transmission line 320, a crossover 330 and a via 340. As shown, the inductor 310 and the CPW transmission line 320 can be patterned using TaN and a metal contact layer. For example, the inductor 310 and the CPW transmission line 320 can be patterned using TaN, and a metal contact layer (M1) can be patterned on top of the TaN. In this embodiment, the inductor 310 and the CPW transmission line 320 can be patterned using TaN and the metal contact layer using the same lithographic rules. This allows the inductor 310 and CPW transmission line 320 to operate at both low temperatures and at room temperature. For example, when operating at low temperatures (e.g., temperatures wherein TaN superconducts) the TaN will dominate and the inductor 310 and CPW transmission line 320 will superconduct. When operating at room temperatures, the metal will dominate, allowing the inductor 310 and CPW transmission line 320 to still operate using normal conductivity through the metal contact layer. It should be appreciated that the metal contact layer can be patterned using any suitable metal or metal alloy, such as, but not limited to, gold, copper and/or aluminum. Furthermore, it should be appreciated that additional elements and/or structures not shown in FIGS. 2 and 3 can be patterned using TaN. For example, the TaN layer can additionally comprise an interconnect and/or any form of transmission line, such as a microstrip. An advantage of such a device is that it can operate at both room temperature and at superconducting temperatures.

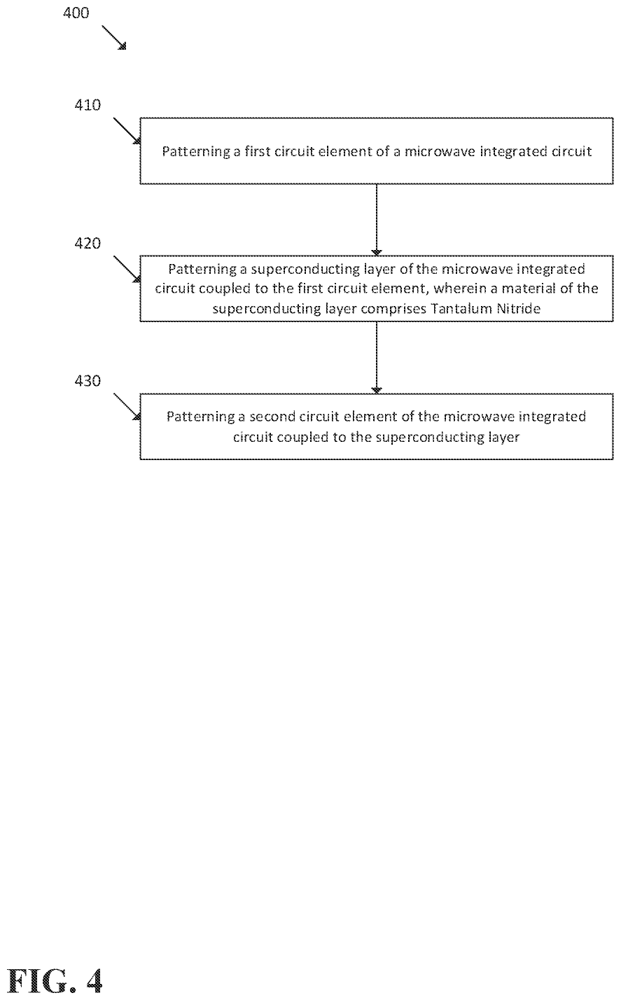

FIG. 4 illustrates a flow diagram of an example, non-limiting method 400 that can facilitate a process to fabricate a device constructed in accordance with one or more embodiments described herein. Repetitive description of like elements and/or processes employed in respective embodiments is omitted for sake of brevity.

At 410, method 400 can comprise patterning a first circuit element of a microwave integrated circuit.

At 420, method 400 can comprise patterning a superconducting layer (e.g., superconducting passive elements 200 and/or 300) of the microwave integrated circuit coupled to the first circuit element, wherein a material of the superconducting layer comprises Tantalum Nitride.

At 430, method 400 can comprise patterning a second circuit element of the microwave integrated circuit coupled to the superconducting layer.

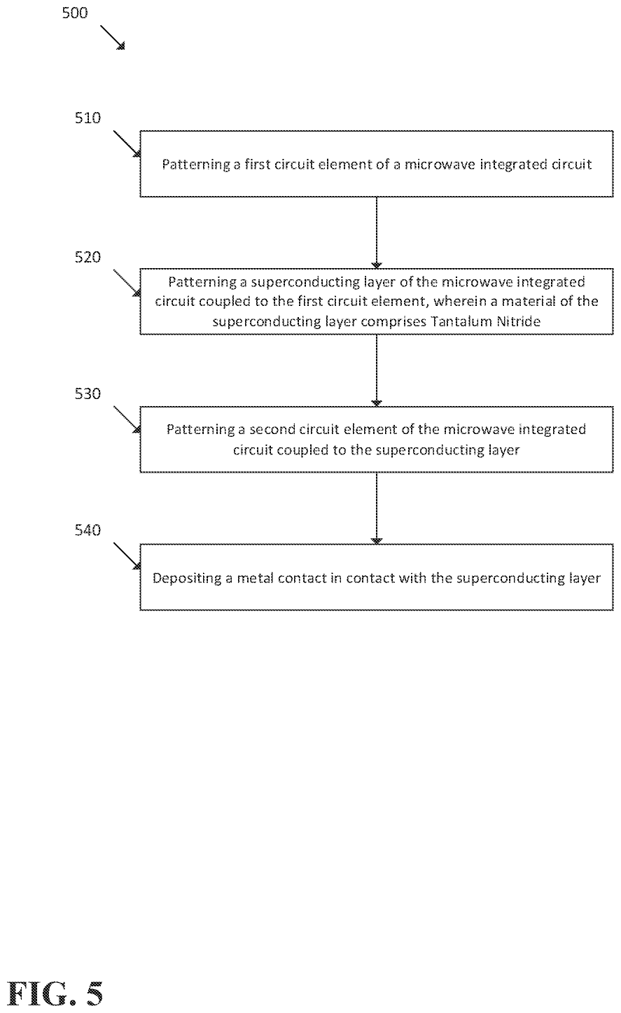

FIG. 5 illustrates a flow diagram of an example, non-limiting method 500 that can facilitate a process to fabricate a device constructed in accordance with one or more embodiments described herein. Repetitive description of like elements and/or processes employed in respective embodiments is omitted for sake of brevity.

At 510, method 500 can comprise patterning a first circuit element of a microwave integrated circuit.

At 520, method 500 can comprise patterning a superconducting layer (e.g., superconducting passive elements 200 and/or 300) of the microwave integrated circuit coupled to the first circuit element, wherein a material of the superconducting layer comprises Tantalum Nitride.

At 530, method 500 can comprise patterning a second circuit element of the microwave integrated circuit coupled to the superconducting layer.

At 540, method 500 can comprise depositing a metal contact in contact with the superconducting layer.

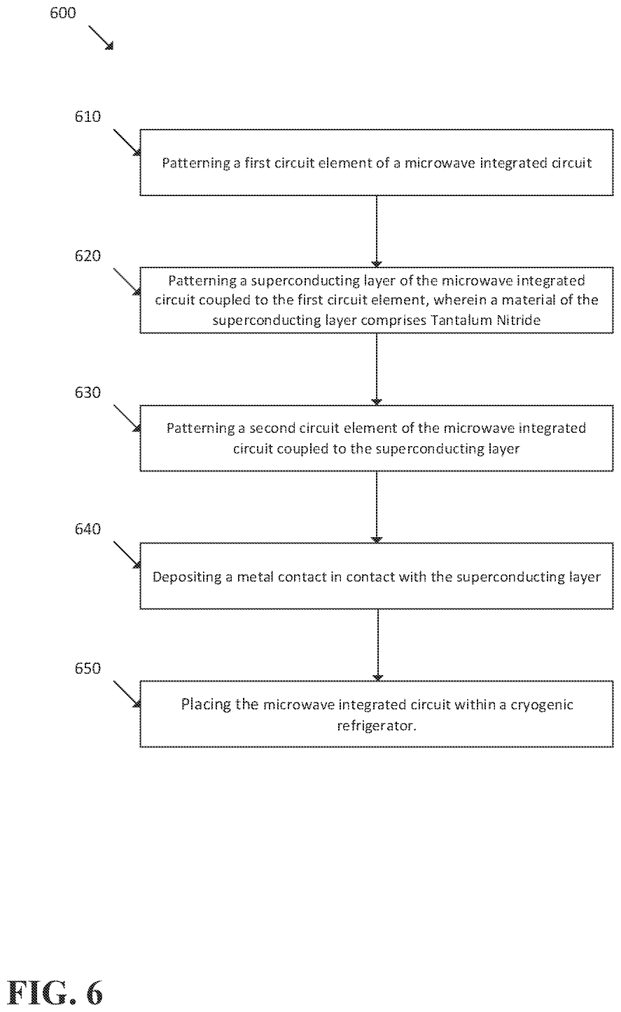

FIG. 6 illustrates a flow diagram of an example, non-limiting method 600 that can facilitate a process to fabricate a system constructed in accordance with one or more embodiments described herein. Repetitive description of like elements and/or processes employed in respective embodiments is omitted for sake of brevity.

At 610, method 600 can comprise patterning a first circuit element of a microwave integrated circuit.

At 620, method 600 can comprise patterning a superconducting layer (e.g., superconducting passive elements 200 and/or 300) of the microwave integrated circuit coupled to the first circuit element, wherein a material of the superconducting layer comprises Tantalum Nitride.

At 630, method 600 can comprise patterning a second circuit element of the microwave integrated circuit coupled to the superconducting layer.

At 640, method 600 can comprise depositing a metal contact in contact with the superconducting layer.

At 650, method 600 can comprise placing the microwave integrated circuit within a cryogenic refrigerator. For example, the microwave integrated circuit can be included as part of a transmission line within a cryogenic refrigerator of a quantum computer, thereby enabling superconducting transmission of control and/or readout signals from the qubits of the quantum computer.

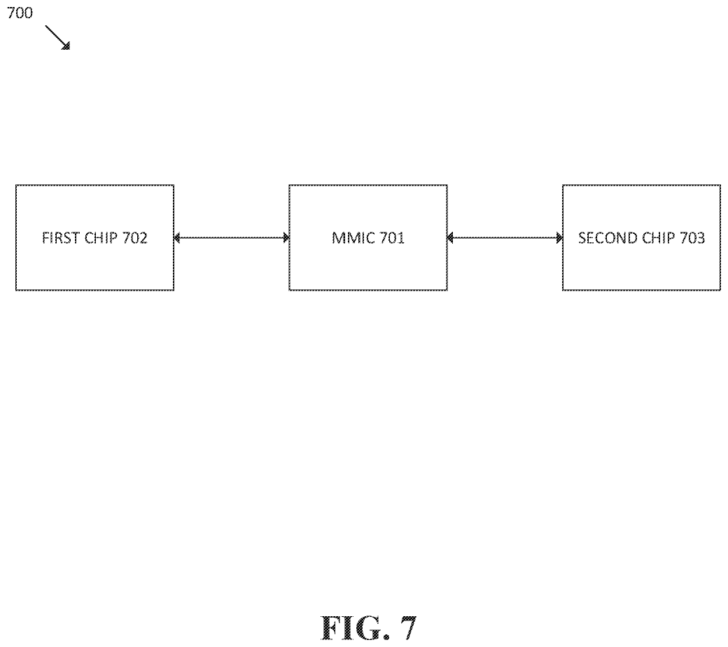

FIG. 7 illustrates a block diagram of an example, non-limiting device 700, in accordance with one or more embodiments describe herein. Repetitive description of like elements and/or processes employed in respective embodiments is omitted for sake of brevity.

Device 700 can comprise a MMIC 701 comprising a superconducting layer of TaN, as described in greater detail in reference to FIGS. 2 and 3 above. The MMIC 701 can be coupled to a first chip 702 and a second chip 703. For example, a signal can pass from the first chip 702 through the MMIC 701 to the second chip 703. In an embodiment, device 700 can be part of a quantum computing system located in a cryogenic system. Accordingly, when the MMIC 701 is at or below the critical temperature of the TaN in the superconducting layer, the MMIC 701 can superconduct. In an embodiment, the MMIC 701 can further comprise a metal contact layer deposited on top of the superconducting layer as described in greater detail above in reference to FIG. 3. Accordingly, if the MMIC 701 is not at or below the critical temperature of the TaN in the superconducting layer, the MMIC 701 can still pass a signal between the first chip 702 and the second chip 703. It should be appreciated that the first chip 702 and the second chip 703 can comprise any circuit elements and/or components utilized in a quantum computing system. For example, as described above, the first chip 702 and/or the second chip 703 can comprise a resistor, such as that used for biasing or termination.

In an embodiment, a method for use of a superconducting monolithic microwave integrated circuit can comprise, operating the superconducting monolithic microwave integrated circuit, wherein the superconducting monolithic microwave integrated circuit can comprise a superconducting passive element coupled to a first circuit element and to a second circuit element, wherein a material of the superconducting passive element comprises Tantalum Nitride. For example, the superconducting passive element can be cooled to a temperature at which Tantalum Nitride superconducts. An electric current can then be passed from the first circuit element, across the superconducting passive elements, and to the second circuit element.

An advantage of such methods, devices, and/or systems is that they enable superconducting MMICs, while limiting the time and resource utilized to develop fabrication processes for superconducting MMICs. For example, by patterning elements within the MMIC, such as inductors and transmission lines within a TaN layer, the elements will superconduct when at low temperatures due to the superconductive properties of TaN discussed above in detail. It should be appreciated that the devices, systems, apparatuses and methods described herein can be utilized with other superconducting materials. For example, in an embodiment aluminum can be used to pattern one or more superconducting elements as described herein, as aluminum superconducts at temperatures below 1.2K.

In view of one or more embodiments described herein, a practical application of the devices described herein is that they offer improved performance, due to the superconductivity, while also decreasing costs associated with developing fabrication costs, which can lead to decreased production costs. As such, the devices describe herein can enable scalability and greater adoption rates due to decreased production costs.

What is claimed is:

1. A device, comprising:
a monolithic microwave integrated circuit comprising a superconducting passive element coupled to a first circuit element and to a second circuit element, wherein a material of the superconducting passive element comprises Tantalum Nitride.

2. The device of claim 1, wherein the superconducting passive element comprises an inductor coupled to the first circuit element and to the second circuit element.

3. The device of claim 1, wherein the superconducting passive element comprises a transmission line coupled to the first circuit element and to the second circuit element.

4. The device of claim 1, wherein the superconducting passive element comprises an interconnect coupled to the first circuit element and to the second circuit element.

5. The device of claim 1, wherein the superconducting passive element comprises a coplanar waveguide coupled to the first circuit element and to the second circuit element.

6. The device of claim 1, wherein the superconducting passive element comprises a microstrip coupled to the first circuit element and to the second circuit element.

7. The device of claim 1, further comprising:
a metal contact on the superconducting passive element.

8. The device of claim 7, wherein the metal contact comprises at least one of Gold, Copper or Aluminum.

9. A method, comprising:
operating a superconducting monolithic microwave integrated circuit, wherein the superconducting monolithic microwave integrated circuit comprises:
a superconducting passive element coupled to a first circuit element and to a second circuit element, wherein a material of the superconducting passive element comprises Tantalum Nitride.

10. The method of claim 9, wherein the superconducting passive element further comprises an inductor.

11. The method of claim 9, wherein the superconducting passive element further comprises a transmission line.

12. The method of claim 9, wherein the superconducting passive element further comprises an interconnect.

13. The method of claim 9, wherein the superconducting monolithic microwave integrated circuit further comprises a metal contact on the superconducting passive element.

14. A system, comprising:
a cryogenic refrigerator; and
a monolithic microwave integrated circuit comprising a superconducting layer coupled to a first circuit element and to a second circuit element, wherein a material of the superconducting layer comprises Tantalum Nitride, and wherein the monolithic microwave integrated circuit is located within the cryogenic refrigerator.

15. The system of claim 14, wherein the superconducting layer comprises an inductor coupled to the first circuit element and to the second circuit element.

16. The system of claim 14, wherein the superconducting layer comprises a transmission line coupled to the first circuit element and to the second circuit element.

17. The system of claim 14, wherein the superconducting layer comprises an interconnect coupled to the first circuit element and to the second circuit element.

18. The system of claim 14, wherein the superconducting layer comprises a coplanar waveguide coupled to the first circuit element and to the second circuit element.

19. The system of claim 14, wherein the superconducting layer comprises a microstrip coupled to the first circuit element and to the second circuit element.

20. The system of claim 14, wherein the monolithic microwave integrated circuit further comprises a metal contact on the superconducting layer coupled to the first circuit element and to the second circuit element.
